(19) United States
(12) Patent Application Publication
(10) Pub. No.: US 2026/0096427 A1
(43) Pub. Date: Apr. 2, 2026

(54) CRYOGENIC CHIP-ON-CHIP ASSEMBLIES WITH THROUGH SUBSTRATE VIAS AND METHODS OF FORMING THEREOF

(71) Applicant: PsiQuantum, Corp., Palo Alto, CA (US)

(72) Inventors: Alexey VERT, Clifton Park, NY (US); Vimal KAMINENI, Mechanicville, NY (US)

(21) Appl. No.: 19/108,632

(22) PCT Filed: Sep. 5, 2023
(86) PCT No.: PCT/US2023/032014

§ 371 Date: Mar. 4, 2025

Related U.S. Application Data
(60) Provisional application No. 63/374,617, filed on Sep. 6, 2022.

(51) Int. Cl. H10W 40/30; H10W 20/00; H10W 20/20

(52) U.S. Cl. CPC H10W 40/30; H10W 20/023; H10W 20/211

(57) ABSTRACT

A device includes a photonic cryo die containing photonic components, and an electronic die bonded to the photonic die, the electronic die containing electrically conductive through substrate vias. The electrically conductive through silicon vias can electrically connect a backside redistribution layer to control circuitry for operation in a cryogenic environment in a compact package that exhibits low resistance and low parasitic capacitance.

### TECHNICAL FIELD

Embodiments herein relate generally to cryogenic photonic and electronic chip assemblies used for quantum computing (QC) applications, and more specifically to through substrate vias used in such assemblies and methods of forming thereof.

### BACKGROUND

A cryostat is a device that is used to maintain cryogenic temperatures (e.g., 120° K or less) for objects or materials located within the cryostat. Cryostats have been used for a number of applications in which cryogenic temperatures are desirable and/or necessary. For example, many types of quantum computing (QC) systems require quantum processing operations to be performed at extremely low temperatures. A cryostat may be used to house components of the QC system used to perform quantum processing operations such that these components may be maintained within a specified cryogenic temperature range.

### SUMMARY

According to one embodiment, a device includes a photonic cryo die containing photonic components, and an electronic die bonded to the photonic die, the electronic die containing electrically conductive through substrate vias.

According to another embodiment a method of making a hybrid electronic/photonic package comprises providing a photonic die comprising photonic components, providing an electronic die, and bonding the electronic die to the photonic die such that at least one of a cavity and an underfill material having a lower thermal conductivity than materials of the photonic die and the electronic die is located between the photonic die and the electronic die.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1A is a simplified schematic diagram illustrating an optical switch, according to some embodiments.

FIG. 1B is an illustration of a user interfacing with a hybrid quantum computing device, according to some embodiments.

FIG. 2 is a vertical cross-sectional view of a hybrid electronic/photonic package including a cryo die and a secondary die, according to various embodiments.

FIG. 3 is a vertical cross-sectional view of a further hybrid electronic/photonic package including a cryo die and a secondary die with through substrate vias, according to various embodiments.

FIG. 4 is a vertical cross-sectional view of a secondary die containing through substrate vias and backside interconnects, according to various embodiments.

FIG. 5 shows a flow diagram of a method for fabricating cryogenic dies, in accordance with some example embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

Reference will now be made in detail to embodiments, examples of which are illustrated in the accompanying drawings. In the following detailed description, numerous specific details are set forth to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

The following description, for purpose of explanation, is described with reference to specific embodiments. However, the illustrative discussions that follow are not intended to be exhaustive or to limit the scope of the claims to the precise forms disclosed. Many modifications and variations are possible in view of the above teachings. The embodiments were chosen to best explain the principles underlying the claims and their practical applications, to thereby enable others skilled in the art to best use the embodiments with various modifications as are suited to the particular uses contemplated.

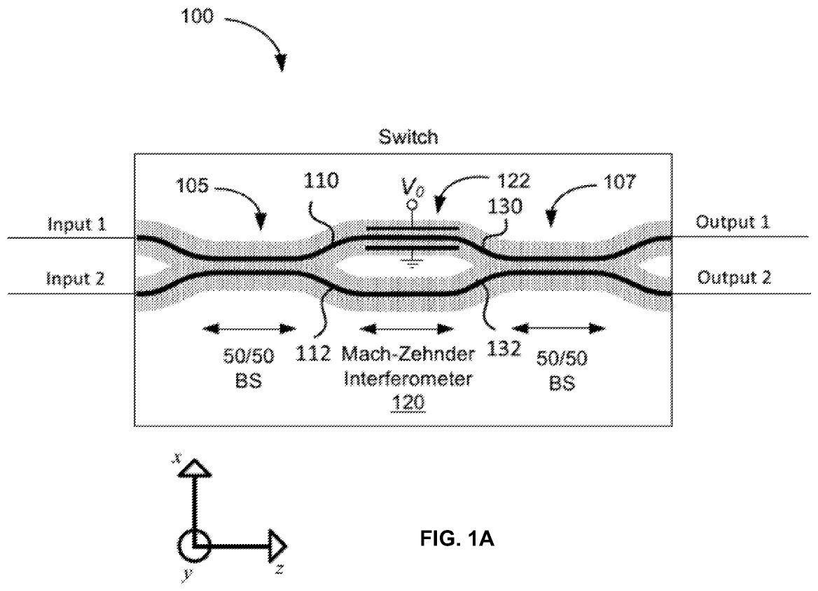

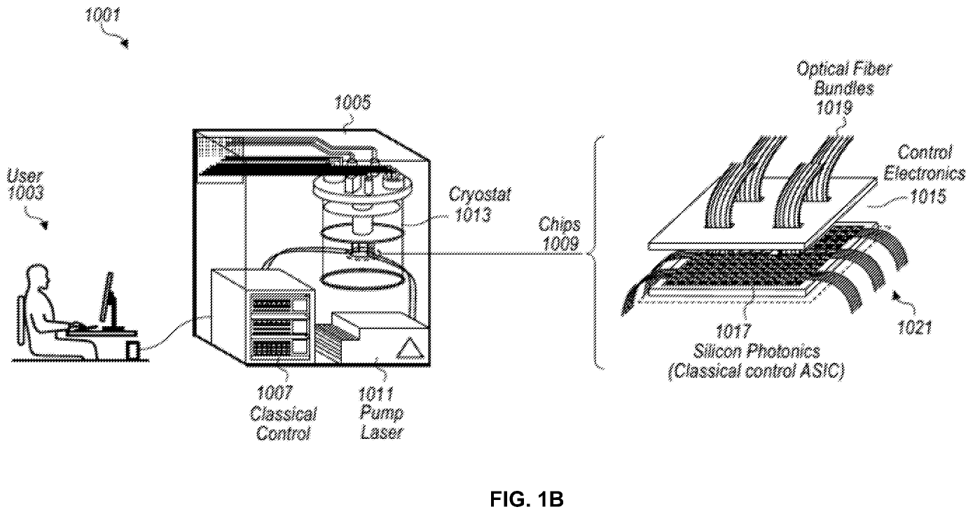

FIG. 1A is a simplified schematic diagram illustrating an optical switch according to an embodiment of this disclosure. Referring to FIG. 1A, switch 100 includes two inputs: Input 1 and Input 2 as well as two outputs: Output 1 and Output 2. As an example, the inputs and outputs of switch 100 can be implemented as optical waveguides operable to support single mode or multimode optical beams. As an example, switch 100 can be implemented as a Mach-Zehnder interferometer integrated with a set of 50/50 beam splitters 105 and 107, respectively. As illustrated in FIG. 1A, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage V₀ can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1A, it will be appreciated that both arms of the Mach-Zehnder interferometer can include phase adjustment sections.

As illustrated in FIG. 1A, electro-optic switch technologies, in comparison to all-optical switch technologies, utilize the application of the electrical bias (e.g., V₀ in FIG. 1A) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1A, embodiments of this disclosure are not limited to this particular switch architecture and other phase adjustment devices are included within the scope of this disclosure, including ring resonator designs, Mach-Zehnder modulators, generalized Mach-Zehnder modulators, and the like. One of ordinary skill in the art would recognize many variations, modifications, and alternatives.

In some embodiments, the optical phase shifter devices described herein may be utilized within a quantum computing system such as the hybrid quantum computing system shown in FIG. 1B. Alternatively, these optical phase shifter devices may be used in other types of optical systems. For example, other computational, communication, and/or technological systems may utilize photonic phase shifters to direct optical signals (e.g., single photons or continuous wave (CW) optical signals) within a system or network, and phase shifter architectures described herein may be used within these systems, in various embodiments.

FIG. 1B is a simplified system diagram illustrating incorporation of an electro-optic switch with a prior art cryostat into a hybrid quantum computing system, according to some embodiments. In order to operate at low temperatures, for example liquid helium temperatures, embodiments of this disclosure integrate the electro-optic switches discussed herein (e.g., see FIG. 1A) into a system that includes cooling systems. Thus, embodiments of this disclosure provide an optical phase shifter that may be used within a hybrid computing system of the type illustrated in FIG. 1B. The hybrid computing system 1001 includes a user interface device 1003 that is communicatively coupled to a hybrid quantum computing (QC) sub-system 1005. The user interface device 1003 may be any type of user interface device, for example, a terminal including a display, keyboard, mouse, touchscreen, and the like. In addition, the user interface device may itself be a computer such as a personal computer (PC), laptop, tablet computer, etc.

In some embodiments, the user interface device 1003 provides an interface with which a user can interact with the hybrid QC subsystem 1005. For example, the user interface device 1003 may run software, such as a text editor, an interactive development environment (IDE), command prompt, graphical user interface, and the like so that the user can program, or otherwise interact with, the QC subsystem to run one or more quantum algorithms. In other embodiments, the QC subsystem 1005 may be pre-programmed and the user interface device 1003 may simply be an interface where a user can initiate a quantum computation, monitor the progress, and receive results from the hybrid QC subsystem 1005. Hybrid QC subsystem 1005 may further include a classical computing system 1007 coupled to one or more quantum computing chips 1009. In some examples, the classical computing system 1007 and the quantum computing chip 1009 can be coupled to other electronic components, e.g., pulsed pump lasers 1011, microwave oscillators, power supplies, networking hardware, etc.

The quantum computing chips 1009 may be housed within a cryostat, for example, cryostat 1013. In some embodiments, each of the quantum computing chips 1009 can include one or more constituent chips, e.g., hybrid electronic chip 1015 and integrated photonics chip 1017. The photonics chip 1017 may include the interferometer 100 shown in FIG. 1A. Signals can be routed on- and off-chip any number of ways, e.g., via optical interconnects (e.g., optical fiber bundles) 1019 and via other electronic interconnects 1021.

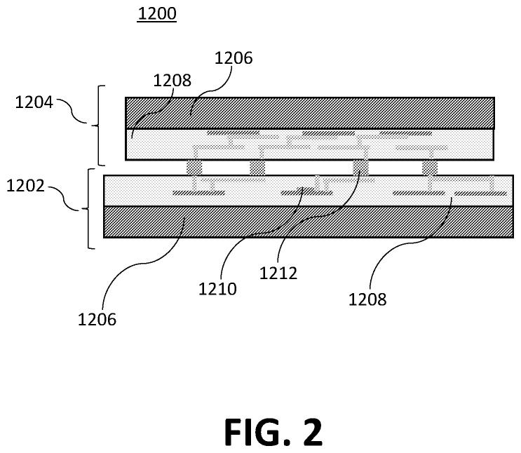

FIG. 2 is a vertical cross-sectional view of a hybrid electronic/photonic package 1200 including a cryo die 1202 (e.g., photonic cryo die) and a secondary die 1204 (electronic cryo die), according to various embodiments. In one embodiment, the package 1200 may comprise one or more quantum computing chips 1009 described above with respect to FIG. 1B. Flip-chip or chip-on-chip (also chip-on-wafer) techniques may be used to form the hybrid electronic/photonic package 1200. Quantum computing systems operating at cryogenic temperatures (e.g., 10K and below), such as systems 1001 described above (e.g., see FIG. 1B and related description) may include two chips co-packaged in close proximity to one another such as the hybrid electronic/photonic package 1200 shown in FIG. 2. Each chip may contain one or more dies in a package. The cryo die 1202 may be configured to perform quantum computing operations and may be part of the photonic chip (e.g., the photonic chip 1017 in FIG. 1B) or may be part of a hybrid electronic/photonic chip including electronic and photonic circuits. The secondary die 1204 may be part of the electronic chip (e.g., the electronic chip 1015 in FIG. 1B) or may be part of a hybrid electronic/photonic chip.

One of the chips (e.g., the chip containing the cryo die 1202) may require strict temperature control to perform quantum computations. For example, the cryo die 1202 may be mounted directly or indirectly to a liquid helium chamber to maintain its temperature at 4.2K or below. For example, the cryo die 1202 may be indirectly mounted to an outer surface of the liquid helium chamber using an interposer.

The other chip (e.g., the secondary die 1204) may provide control functions and may be operated at the cryo temperature of 10K or below, such as 4.2K or below, or at a higher temperature than the 10K cryo temperature. For example, the secondary die 1204 may include classical semiconductor and/or other solid state devices (e.g., transistors, resistors, capacitors, etc.) and serve as a readout interface that may perform classical computations and data processing. Each of the secondary die 1204 and a cryo die 1202 may include a first portion 1206 and a second portion 1208. The first portion 1206 may be include a substrate (e.g., silicon substrate or insulating substrate). The second portion 1208 may include active and passive devices (e.g., interferometers, superconducting wire detectors, transistors, etc.) and interconnects which include various electrical and/or photonic interconnect structures formed in a dielectric material, such as silicon oxide. The cryo die 1202 may include various temperature-sensitive components 1210, such as modulators, interferometers, lasers (e.g., laser based single photon sources) and/or superconducting wire detectors formed within the substrate portion (e.g., first portion) 1206 and/or in the second portion 1208 of the die 1202. The cryo die 1202 and the secondary die 1204 may be bonded to one another using electrically conductive bonding pads (e.g., copper or copper alloy pads) 1212.

As briefly mentioned, the hybrid quantum computing system shown in FIG. 1B are typically operating at cryogenic temperatures (e.g., 10K and below) and usually require control electronics to be operational at low temperatures as well. As such, to reduce resistance of conductor wires at cryogenic temperatures, it is desirable for the control electronics in the hybrid quantum computing system shown in FIG. 1B to include low resistance conductor wires that can provide relatively robust power delivery and good signal integrity at cryogenic temperatures. The embodiments of the present disclosure provide a structure of a hybrid electronic/photonic package for power and signal delivery to the cryogenic control electronics through low resistance path using through substrate vias.

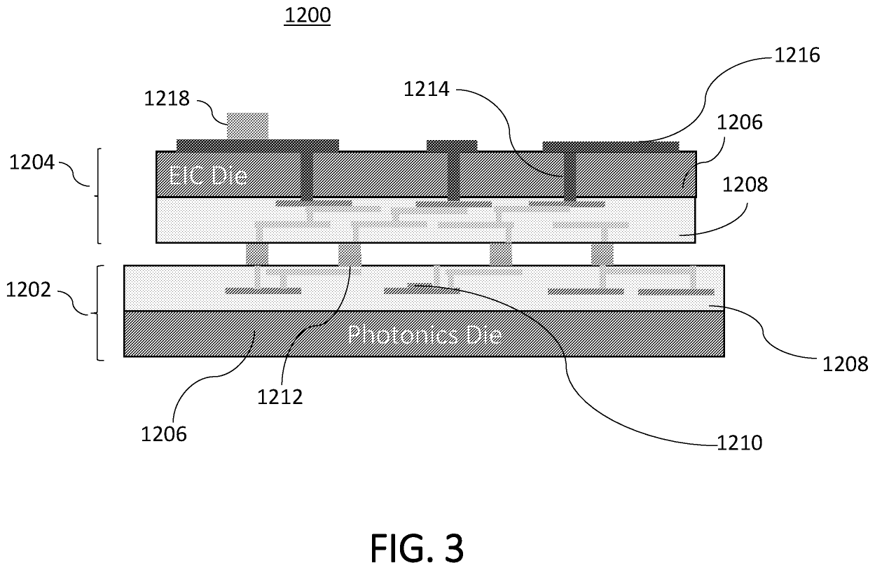

FIG. 3 is a vertical cross-sectional view of an embodiment hybrid electronic/photonic package including a cryo die (e.g., photonics die or chip) 1202 bonded to a secondary die 1204 with through substrate vias 1214. The secondary die 1204 may be an electronic die or chip containing electronic integrated circuits (“EIC”) which function as control circuits for the photonic devices of the photonic die 1202. If the substrate 1206 of the secondary die 1204 comprises a silicon substrate (e.g., a silicon wafer or a portion thereof), then the through substrate vias comprise through silicon vias (TSVs).

The TSVs 1214 provide a low resistance path to the control circuits located in the second portion 1208 of the secondary die 1204 through a backside redistribution layer (RDL) 1216. The second portion 1208 is located on a front side of the substrate 1206 and the RDL is located on the opposing backside of the substrate 1206 of the secondary die 1204.

As shown in FIG. 3, the TSVs 1214 may comprise solid core TSVs which lack a gap in their inner core. The TSVs 1214 may be made of an electrically conductive material, such as a metal or metal alloy, for example copper or copper alloy, such that low resistance paths can be formed through the substrate.

In one embodiment, when the bonded assembly 1200 freezes at cryo temperatures, the dopants in a bulk silicon substrate 1206 may freeze out, thus dropping the parasitic capacitance of TSVs 1214 extending through the substrate 1206 close to zero. As such, the conductive material of the TSVs 1214 may be in contact with the semiconductor (e.g., silicon) material of the substrate 1206 without creating a significant parasitic capacitance between laterally adjacent TSVs 1214. Thus, in one embodiment, the TSVs 1214 comprise uninsulated, solid core conductive vias which lack an insulating shell between the solid conductive (e.g., copper) core and the semiconductor (e.g., silicon) substrate 1206 through which the vias extend. Likewise, the backside RDL 1216 may directly contact the backside of the semiconductor substrate 1206 without an intervening insulating layer between them.

In various embodiments, the TSVs 1214 may be used to directly electrically connect the active components (e.g., transistors, etc.) and metal interconnect stacks of the second portion 1208 and to the backside RDL 1216 of the secondary 1204. In some embodiments, bumps or pillars 1218 may be optionally disposed on the backside RDL 1216 to provide external electrical connections to the bonded assembly 1200. As such, the solid core TSVs 1214 can provide low resistance path to the control circuit of the photonic cryo die 1202 to implement efficient power delivery and signal input/output (I/O) of the interconnects (e.g., back-end-of-line (BEOL)) components of the bonded assembly 1200.

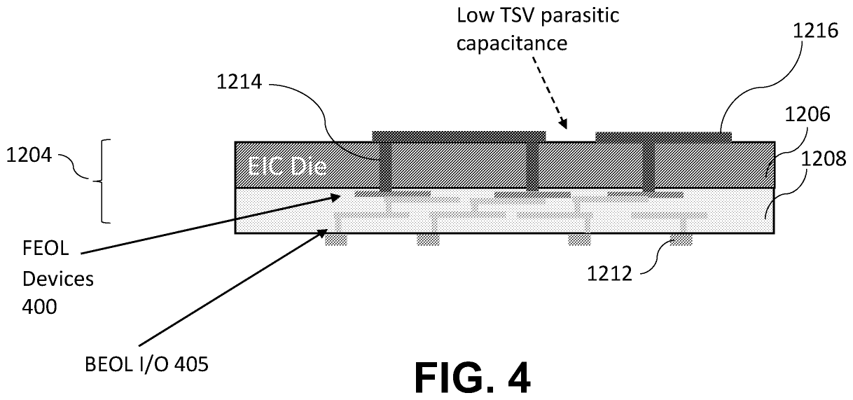

Assuming the backside RDL 1216 is connected to vicinity of front-end-of-line (FEOL) components of the control circuit of the secondary die 1204, the backside RDL 1216 can also function as low-resistance interconnects between the FEOL components of the control circuit at cryogenic temperatures. FIG. 4 is a vertical cross-sectional view of an embodiment secondary die 1204 with solid core TSVs 1214 which are interconnected to each other using backside RDL 1216 interconnects, according to various embodiments. Thus, the backside RDL 1216 may be used to interconnect the TSVs 1214 to implement low resistance between the FEOL devices 400 in the control circuit at cryogenic temperatures. This allows the control circuit components (e.g., BEOL I/O 405) located in the second portion 1208 over the front side of the substrate 1206 of the secondary die 1204 to be interconnected among each other through the backside of the substrate 1206, thus saving room over the front side of the substrate 1206 for other components. Furthermore, the backside RDL 1216 interconnects can significantly reduce parasitic capacitance (e.g., between TSVs) at cryogenic operational temperatures, in accordance with some example embodiments.

According to various embodiments, the minimum dimension TSVs and backside RDLs may be 1 μm or greater. The minimum dimension may be a diameter of TSVs or a thickness of the RDLs. In one embodiment, the diameter of the solid core TSVs 1214 may range from 1 μm to 10 μm. In one embodiment, the depth of the TSVs 1214 through the substrate 1206 may range from 10 μm to 100 μm. In one embodiment, the backside RDL may have a thickness (i.e., line width) of 1 μm to 10 μm. In one implementation, the backside RDL may have a thickness ranging from 2 μm to 4 μm. The dimension of the TSVs provides a low resistance path for high device performance at cryogenic temperatures. As such, the resistance of the TSVs can be reduced significantly when temperature changes from room temperature to cryogenic temperature.

Table 1 shows comparisons of resistance of solid copper electrical paths (e.g., interconnects, pads, TSVs) at different width/thickness (where the wire width equals to its thickness) at room temperature of 300K and at cryogenic temperature of 4K. As shown in Table 1, the resistance of copper paths having a thickness and width of 1-5 μm may be reduced 20 to 30 times when the temperature drops from 300K to 4K.

TABLE 1
Comparison of solid copper interconnect resistance at 300K and 4K

| | |
|---|---|
| Cu wire thickness/width*, | Resistance reduction |
| μm | from 300K → to → 4K |

| | | |
|---|---|---|
| 1-5 | μm | ~20-30X |
| 0.5 | μm | ~10X |
| 0.1 | μm | ~2X |
| 0.05 | μm | ~1X |

As shown in Table 1, for copper components (e.g., TSV and/or RDL formed of copper) having dimensions of 1 micron or greater, the amount of resistance reduction at cryogenic temperatures is at least a factor of 10 greater than the amount of resistance reduction for wire dimensions of 0.5 microns or less.

The present disclosure also provides a method of fabricating a silicon substrate 1206 having the TSVs 1214. The method includes forming through silicon openings through the substrate 1206 using photolithography and etching, followed by filling the openings with an electrically conductive material, such as copper, to form the TSVs 1214. The copper may be deposited by electroplating or electroless plating, for example. The TSVs 1214 may be exposed on the backside of the substrate 1206 followed by forming the backside RDL 1216 in contact with the TSVs 1214. Alternatively, the TSVs 1214 and the backside RDL 1216 may be formed during the same deposition step by depositing copper in the openings and on the backside of the substrate 1206. The copper layer on the backside of the substrate 1206 is then patterned by photolithography and etching to form the backside RDL 1216.

The resistance of the conductive paths in the bonded assembly 1200 can be significantly reduced by using the through silicon vias (TSVs) in the silicon substrate and backside redistribution layer (RDL) interconnects located on the back side of the silicon substrate in quantum computing chip on chip, chip on wafers, stacked die or hybrid bonded die or wafer quantum computing systems at cryogenic temperatures. The TSVs may be directly connected to the active FEOL components and metal stacks of electronic integrated circuits, and may be connected to the backside RDL. As such, the signal integrity and power distribution in the substrate can be improved at cryogenic temperatures.

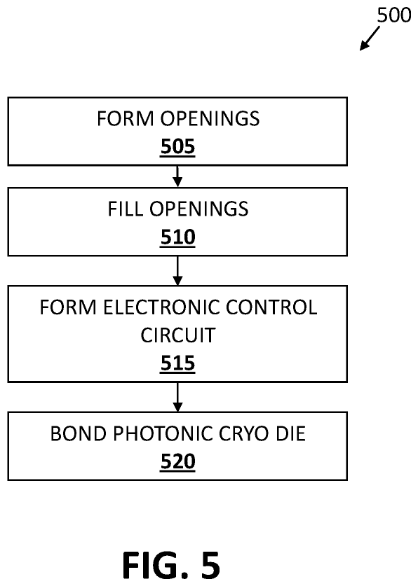

FIG. 5 shows a flow diagram of a method 500 for fabricating cryogenic dies, in accordance with some example embodiments. At operation 505, openings are formed. For example, through silicon openings are formed through a substrate (e.g., substrate 1206) of an electronic die (e.g., cryo electronic die).

At operation 510, the openings are filled. For example, electrically conductive material, such as copper, is used to fill the openings to form TSVs. At operation 515, an electrical control circuit is formed. For example, the die my undergo front-end-of-line (FEOL) and back-end-of-line (BEOL) processing to form an electrical circuit, which can connect to an optical chip (e.g., cryo photonic die).

At operation 520, the electronic die is bonded to a cryo photonic die to provide electrical input and output interface with the cryo photonic die for operation in a cryogenic environment, as discussed above.

The following are example embodiments:

Example 1: A device, comprising: a photonic cryo die comprising photonic components; and an electronic die bonded to the photonic die, the electronic die containing electrically conductive through substrate vias.

Example 2: The device as example 1 describes, wherein the photonic cryo die is configured to operate at a temperature ranging from OK to 10K.

Example 3: The device as either of examples 1 or 2 describe, wherein the through substrate vias extend through a substrate of the electronic die.

Example 4: The device as any of examples 1-3 describe, wherein the electronic die further comprises an electrically conductive backside redistribution layer (RDL) disposed on backside of the substrate and electrically connected to the through substrate vias.

Example 5: The device as any of examples 1˜4 describe, wherein the electronic die further comprises control circuit devices which are electrically connected to the through substrate vias and to the photonic cryo die.

Example 6: The device as any of examples 1-5 describe, wherein the substrate comprises a silicon substrate, and the control circuit devices comprise transistors located over a front side of the silicon substrate.

Example 7: The device as any of examples 1-6 describe, wherein a thickness of the backside RDL is equal to or greater than 1 μm.

Example 8: The device as any of examples 1-7 describe, wherein the thickness of the backside RDL ranges from 1 μm to 10 μm.

Example 9: The device as any of examples 1-8 describe, wherein the backside RDL comprises a copper layer.

Example 10: The device as any of examples 1-9 describe, wherein a diameter of each of the through substrate vias is equal to or greater than 1 μm.

Example 11: The device as any of examples 1-10 describe, wherein the diameter of each of the through substrate vias ranges from 1 μm to 10 μm.

Example 12: The device as any of examples 1-11 describe, wherein a depth of each of the through substrate vias ranges from 10 μm to 100 μm.

Example 13: The device as any of examples 1-12 describe, wherein the through substrate vias comprise copper vias.

Example 14: The device as any of examples 1-13 describe, wherein the substrate comprises a semiconductor substrate and the electrically conductive through substrate vias directly contact semiconductor material of the semiconductor substrate.

Example 15: The device as any of examples 1-14 describe, wherein the substrate comprises a silicon substrate, and the through substrate vias comprise solid core through silicon vias which lack an insulating shell between a solid conductive core and the silicon substrate.

Example 16: The device as any of examples 1-15 describe, further comprising a cryostat housing a bonded assembly of the photonic cryo die and the electronic die.

Example 17: The cryo electronic die as any of examples 1-16 describe, wherein the through substrate vias comprise copper vias.

Example 18: A method, comprising: forming openings through a substrate; filling the openings with electrically conductive through substrate vias; forming an electronic control circuit over a front side of the substrate in electrical contact with the through substrate vias; and bonding a photonic cryo die comprising photonic components to the electronic control circuit.

Example 19: The method as example 18 describes, further comprising forming an electrically conductive backside redistribution layer (RDL) on a backside of the substrate.

Example 20: The method as either of examples 18 or 19 describe, wherein the through substrate vias have a diameter of at least 1 micron.

Example 21: The method as any of examples 18-20 describe, further comprising placing the photonic cryo die into a cryostat.

Example 22: A cryo electronic die, comprising: a substrate; a plurality of through substrate vias that extend through the substrate of the cryo electronic die; a redistribution layer on a backside of the substrate, the redistribution layer being electrically conductive, the redistribution layer being electrically connected to the through substrate vias; and a control circuit on a front side of the substrate, the control circuit being electrically connected to the through substrate vias, the through substrate vias electrically connecting the redistribution layer to the control circuit.

Example 23: The cryo electronic die as example 22 describes, wherein the electronic cryo die is configured to operate at a temperature ranging from OK to 10K such that the through substrate vias exhibit reduced resistance and reduced parasitic capacitance.

Example 24: The cryo electronic die as either of examples 22 or 23 describe, wherein a thickness of redistribution layer is equal to or greater than 1 μm.

Example 25: The cryo electronic die as any of examples 22-24 describe, wherein the thickness of the redistribution layer ranges from 1 μm to 10 μm.

Example 26: The cryo electronic die as any of examples 22-25 describe, wherein the redistribution layer comprises a copper layer.

Example 27: The cryo electronic die as any of examples 22-26 describe, wherein a diameter of each of the through substrate vias is equal to or greater than 1 μm.

Example 28: The cryo electronic die as any of examples 22-27 describe, wherein the diameter of each of the through substrate vias ranges from 1 μm to 10 μm.

Example 29: The cryo electronic die as any of examples 22-28 describe, wherein a depth of each of the through substrate vias ranges from 10 μm to 100 μm.

The terminology used in the description of the various described embodiments herein is for the purpose of describing particular embodiments only and is not intended to be limiting. As used in the description of the various described embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A device, comprising:
a photonic cryo die comprising photonic components; and
an electronic die bonded to the photonic die, the electronic die containing electrically conductive through substrate vias.

2. The device of claim 1, wherein the photonic cryo die is configured to operate at a temperature ranging from OK to 10K.

3. The device of claim 1, wherein the through substrate vias extend through a substrate of the electronic die.

4. The device of claim 3, wherein the electronic die further comprises an electrically conductive backside redistribution layer (RDL) disposed on backside of the substrate and electrically connected to the through substrate vias.

5. The device of claim 4, wherein the electronic die further comprises control circuit devices which are electrically connected to the through substrate vias and to the photonic cryo die.

6. The device of claim 5, wherein the substrate comprises a silicon substrate, and the control circuit devices comprise transistors located over a front side of the silicon substrate.

7. The device of claim 5, wherein a thickness of the backside RDL is equal to or greater than 1 μm.

8. The device of claim 7, wherein the thickness of the backside RDL ranges from 1 μm to 10 μm.

9. The device of claim 5, wherein the backside RDL comprises a copper layer.

10. The device of claim 1, wherein a diameter of each of the through substrate vias is equal to or greater than 1 μm.

11. The device of claim 10, wherein the diameter of each of the through substrate vias ranges from 1 μm to 10 μm.

12. The device of claim 1, wherein a depth of each of the through substrate vias ranges from 10 μm to 100 μm.

13. The device of claim 1, wherein the through substrate vias comprise copper vias.

14. The device of claim 1, wherein the substrate comprises a semiconductor substrate and the electrically conductive through substrate vias directly contact semiconductor material of the semiconductor substrate.

15. The device of claim 14, wherein the substrate comprises a silicon substrate, and the through substrate vias comprise solid core through silicon vias which lack an insulating shell between a solid conductive core and the silicon substrate.

16. The device of claim 1, further comprising a cryostat housing a bonded assembly of the photonic cryo die and the electronic die.

17. A method, comprising:
forming openings through a substrate;
filling the openings with electrically conductive through substrate vias;
forming an electronic control circuit over a front side of the substrate in electrical contact with the through substrate vias; and
bonding a photonic cryo die comprising photonic components to the electronic control circuit.

18. The method of claim 17, further comprising forming an electrically conductive backside redistribution layer (RDL) on a backside of the substrate.

19. The method of claim 17, wherein the through substrate vias have a diameter of at least 1 micron.

20. The method of claim 17, further comprising placing the photonic cryo die into a cryostat.

21. A cryo electronic die, comprising:
a substrate;
a plurality of through substrate vias that extend through the substrate of the cryo electronic die;
a redistribution layer on a backside of the substrate, the redistribution layer being electrically conductive, the redistribution layer being electrically connected to the through substrate vias; and
a control circuit on a front side of the substrate, the control circuit being electrically connected to the through substrate vias, the through substrate vias electrically connecting the redistribution layer to the control circuit.

22. The cryo electronic die of claim 21, wherein the electronic cryo die is configured to operate at a temperature ranging from OK to 10K such that the through substrate vias exhibit reduced resistance and reduced parasitic capacitance.

23. The cryo electronic die of claim 21, wherein a thickness of redistribution layer is equal to or greater than 1 μm.

24. The cryo electronic die of claim 23, wherein the thickness of the redistribution layer ranges from 1 μm to 10 μm.

25. The cryo electronic die of claim 21, wherein the redistribution layer comprises a copper layer.

26. The cryo electronic die of claim 21, wherein a diameter of each of the through substrate vias is equal to or greater than 1 μm.

27. The cryo electronic die of claim 26, wherein the diameter of each of the through substrate vias ranges from 1 μm to 10 μm.

28. The cryo electronic die of claim 21, wherein a depth of each of the through substrate vias ranges from 10 μm to 100 μm.

29. The cryo electronic die of claim 21, wherein the through substrate vias comprise copper vias.
